(19) United States
(12) Patent Application Publication
(10) Pub. No.: US 2011/0146766 A1
(43) Pub. Date: Jun. 23, 2011

(54) SOLAR CELLS BASED ON QUANTUM DOT OR COLLOIDAL NANOCRYSTAL FILMS

(75) Inventors: Arthur J. Nozik, Golden, CO (US); Matthew Beard, Golden, CO (US); Matthew D. Law, Golden, CO (US); Joseph M. Luther, Golden, CO (US)

(73) Assignee: SOLAR CELLS BASED ON QUANTUM DOT OR COLLOIDAL NANOCRYSTAL FILMS, Golden, CO (US)

(21) Appl. No.: 12/359,487

(22) Filed: Jan. 26, 2009

Related U.S. Application Data
(60) Provisional application No. 61/031,441, filed on Feb. 26, 2008.

(51) Int. Cl. H01L 31/06; B82Y 20/00; H01L 31/18

(52) U.S. Cl. 136/255; 977/774; 438/93; 257/E31.003

(57) ABSTRACT

Solar cells and methods for use and making these solar cells are disclosed. An exemplary solar cell includes a first electrode. The solar cell also includes a nanocrystal film of a single material disposed in contact with the first electrode. The solar cell also includes a second electrode disposed in contact with the nanocrystal film, not in contact with the first electrode.

The United States Government has rights in this invention under Contract No. DE-AC36-08GO28308 between the United States Department of Energy and the Alliance for Sustainable Energy, LLC, the Manager and Operator of the National Renewable Energy Laboratory.

### BACKGROUND

Quantum Dots (also referred to herein as QDs) are also known as nanocrystals (also referred to herein as NCs), and have been previously proposed for use in solar cell production. However, some such nanocrystal solar cells have previously only exhibited very low conversion efficiencies and some only involved multiple quantum dot materials to create the electron—hole pairs that are separated in the solar cell to generate a photocurrent and a photovoltaic effect. Cracking and shorting of the QD films in previous solar cells based on QDs have also been experienced in a variety of prior attempts to use QD materials in solar cells.

The foregoing examples of the related art and limitations related therewith are intended to be illustrative and not exclusive. Other limitations of the related art will become apparent to those of skill in the art upon a reading of the specification and a study of the drawings.

### SUMMARY

The following embodiments and aspects thereof are described and illustrated in conjunction with systems, tools and methods which are meant to be exemplary and illustrative, not limiting in scope. In various embodiments, one or more of the above-described issues have been reduced or eliminated, while other implementations are directed to other improvements.

In view of the foregoing it is a general aspect of the presently described developments to provide a solar cell made with singular quantum dot material and/or to a method of making or using a solar cell made with singular quantum dot material as shown and described.

In addition to the exemplary aspects and embodiments described above, further aspects and embodiments will become apparent by reference to the drawings and by study of the following descriptions.

### BRIEF DESCRIPTION OF THE DRAWINGS

Exemplary embodiments are illustrated in referenced figures of the drawings. It is intended that the embodiments and figures disclosed herein are to be considered illustrative rather than limiting.

FIG. 1 is an elevational schematic view of an exemplary solar cell;

FIG. 2 is a plan view of a first part of the exemplary solar cell of FIG. 1;

FIG. 3 is a plan view of a further part of the exemplary solar cell of FIG. 1;

FIG. 4 is a plan view of a still further part of the exemplary solar cell of FIG. 1;

FIG. 5 is a plan view like that of FIG. 4, with emphasis;

FIG. 6 is a flow diagram of a process;

FIG. 7, which includes sub-part FIGS. 7a, 7b, 7c and 7d, shows an alternative solar cell and characteristics;

FIG. 8, which includes sub-part FIGS. 8a and 8b, shows characteristics of an alternative solar cell;

FIG. 9, which includes sub-part FIGS. 9a and 9b, shows characteristics of an alternative solar cell;

FIG. 10 shows characteristics of an alternative solar cell;

FIG. 11 shows characteristics of other alternative solar cells;

FIG. 12, which includes sub-part FIGS. 12a and 12b, shows characteristics of alternative solar cells;

FIG. 13, which includes sub-part FIGS. 13a and 13b, shows characteristics of another alternative solar cell;

FIG. 14, which includes sub-part FIGS. 14a and 14b, shows characteristics of a solar cell;

FIG. 15, which includes sub-part FIGS. 15a, 15b and 15c, shows characteristics of a solar cell; and,

FIG. 16 shows characteristics of a solar cell.

### DETAILED DESCRIPTION

Described here is, inter alia, an efficient quantum dot solar cell based on a single quantum dot material. Exemplary solar cells, and methods of use and production thereof may be better understood with reference to the figures and following discussion.

An exemplary device may employ an array of quantum dots composed of a single semiconductor material that forms the light-absorbing layer in a photovoltaic solar cell. The solar cell may be formed by a transparent conductive film (in some examples, indium tin oxide and in other examples an appropriate thin metal layer or a thin heavily doped bulk semiconductor layer) supported on a substrate such as glass upon which a dense layer of quantum dots (also called nanocrystals (also referred to herein as NCs)) is deposited at room temperature to contact the transparent conducting film in a unique way to build a dense QD film without structural stress, leading to a pinhole and crack-free film of electronically coupled quantum dots on the conductive glass. An appropriate metal electrode is then evaporated on the top surface of the quantum dot film to complete the cell structure. Alternatively, if the first electrode layer is a heavily doped semiconductor then a heavily doped bulk semiconductor layer of opposite conductivity type to the first layer may be deposited on top of the QD film Under illumination through the glass, photons are absorbed in the QD film thereby generating excitons which are then dissociated by the electric fields present in the photoactive quantum dot layer. The separated electrons and holes are transported to the separate cathodic and anodic contacts to produce a photovoltaic effect. The electric field in the QD layer can be produced through a Schottky junction formed between the QD film and the evaporated top metal layer or by the use of two different metal layers with different work functions operating as the two electrodes of the cell or by heavily doped semiconductor layers of opposite conductivity type (ie n⁺ and p⁺ layers). In the former case, the Schottky junction forms a space charge layer wherein the electric field is confined to the finite width of the space charge layer that is thinner than the thickness of the QD film. In the latter two cases case with the two different metal electrodes with different work functions or the n⁺-QD layer-p⁺ configuration, an electric field is created across the total width of the QD layer. These latter two electrode arrangements may improve the charge collection and hence the conversion efficiency of the QD solar cell.

Previous attempts describing the construction of solar cells from quantum dots and nanocrystals involved multiple quantum dot materials or multiple electron and hole conducting phases. Also, some previous cells required sintering the nanoparticles together or dispersing the nanocrystals in conductive polymers to transport photogenerated carriers. The present quantum dot cell structures are the first which contain only one quantum dot material formed without thermal processing which acts to accomplish three functions: (1) absorb the light to create electrons and holes, (2) separate the electrons and holes from each other, and (3) transport the electrons and holes to the cell anode and cathode all within a single quantum dot material.

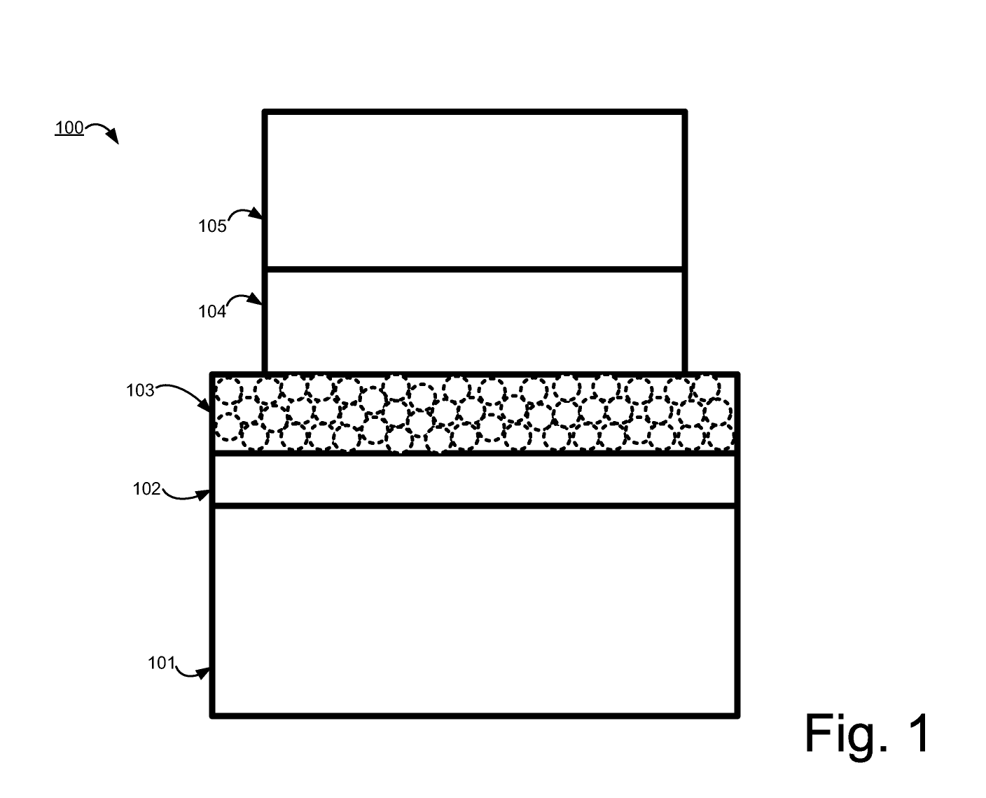

An exemplary QD film photovoltaic (also referred to as PV) device 100 is shown in the drawings, as e.g., in FIG. 1, including a substrate 101 that transmits sunlight, a first electrode material 102 on the substrate that also transmits sunlight, a QD film 103 (shown in FIG. 1 schematically as a plurality of dots, here, arbitrarily dashed line circles, understanding that no particular shape or form of QD material is intended as limiting the scope, the dots may be circular or non-circular or of a plurality of other shapes) over the first electrode, and a second electrode 104 thereover. Here, a conductive third electrode which also acts as an encapsulant 105 is also included over the second electrode. In a particular example, the substrate 101 may be glass, the first electrode 102 a thin layer of indium tin oxide (also known as ITO), the QD material 103 a film of a single QD material, here in various implementations particularly formed either of lead sulfide (PbS) or lead selenide (PbSe) or cadmium selenide (CdSe) (though other semiconductor NCs, core-shell and ternary nanocrystals will work as well, e.g. lead telluride (PbTe), lead selenide sulfide (PbSSe), lead selenide core with lead sulfide shell, cadmium lead sulfide (CdPbS), cadmium lead selenide (CdPbSe) tin sulfide (SnS), tin selenide (SnSe), tin telluride (SnTe), silicon (Si), germanium (Ge), indium arsenide (InAs), indium phosphide (InP), indium antimonide (InSb), gallium arsenide (GaAs), indium gallium arsenide (InGaAs) and all other Group III-V, IV, II-VI, IV-VI compounds and alloys, inter alia). The second electrode 104 may be calcium (Ca) and the encapsulant 105 may be aluminum (Al), though only one or the other may be used alone (calcium works well with the QD material as described below, however, it is highly susceptible to oxidation and thus works better with an encapsulant such as aluminum). Note, the second electrode need not have an encapsulant and may in some examples be just aluminum, or just gold, or just silver or just magnesium, or other metal.

To manufacture a device 100; in one example, about 100 mg. of a sample (e.g., PbS QDs or PbSe QDs that have their first absorption peaks at 1800 nm and 1867 nm, respectively) can be combined in a vial with hexane until the total volume is approximately 15 ml. The QD solution may then be poured into a small 30 ml beaker in a glovebox. For the purpose of ligand exchange described below, an adjacent beaker may be maintained containing about 1% by weight 1,2 ethanedithiol (EDT) dissolved in degassed acetonitrile. Other nucleophillic molecules can be used instead including but not limited to methylamine, benzenedithiol, ethanethiol, ethylenediamine, butylamine, benzenediamine.

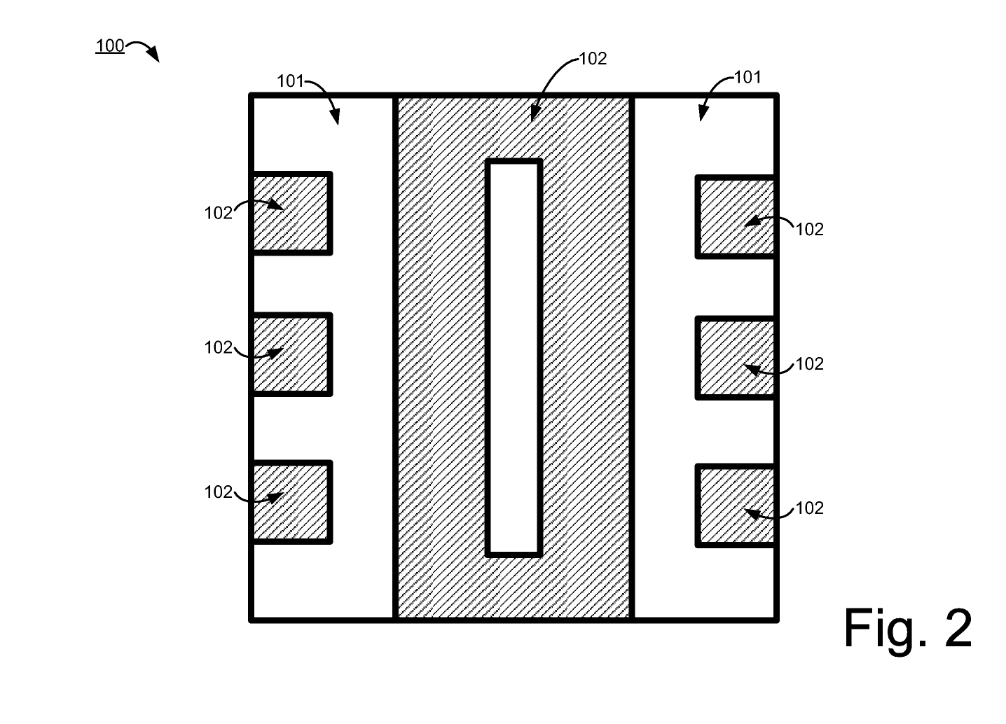

A glass substrate 101 with ITO 102 deposited thereon is then obtained (manufactured by known techniques). An exemplary ITO coated glass substrate with ITO pattern is shown in FIG. 2. This may be cleaned and dried under nitrogen flow and moved into the glovebox.

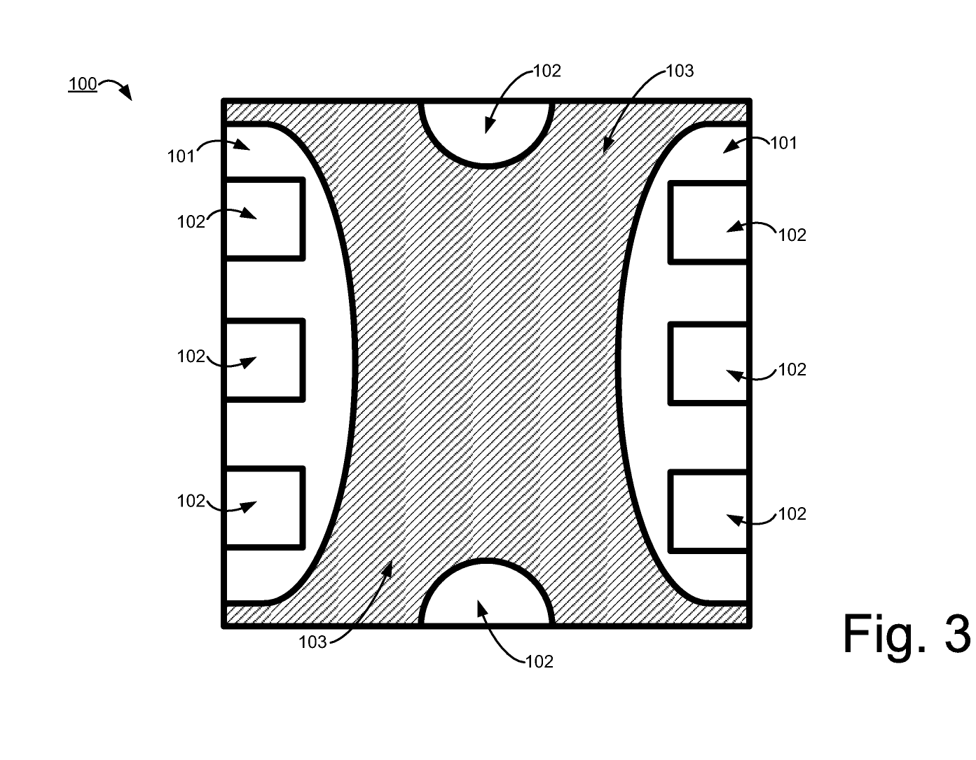

Then, the QD material 103 is added to form the device 100 of FIG. 3. Here, the QD film deposition is a layer by layer technique where the substrate is held at one end, in an exemplary small scale case, e.g., with tweezers, and submerged in the ethane dithiol (EDT) solution for about 5 seconds and removed. The surface is allowed to dry, which takes approximately 10-20 seconds. The substrate is then submersed into the QD solution for roughly 5 seconds. The substrate is removed, allowed to completely dry and treated by resubmersing it in the EDT solution. The process of dipping in the QD, removing very slowly, and treating with EDT is repeated for a number of times (in some examples, a total of 8 times, in other examples, up to 20 times), until the substrate is darkly colored with the QD layer. After the final EDT soak, the back of the substrate may be cleaned to remove the QDs (in small scales, a razor blade may be used). The top surface may then also be cleaned (also in small scale with a razor blade) such that the side ITO pads 102 are visible again. An exemplary film 103 is shown in FIG. 3.

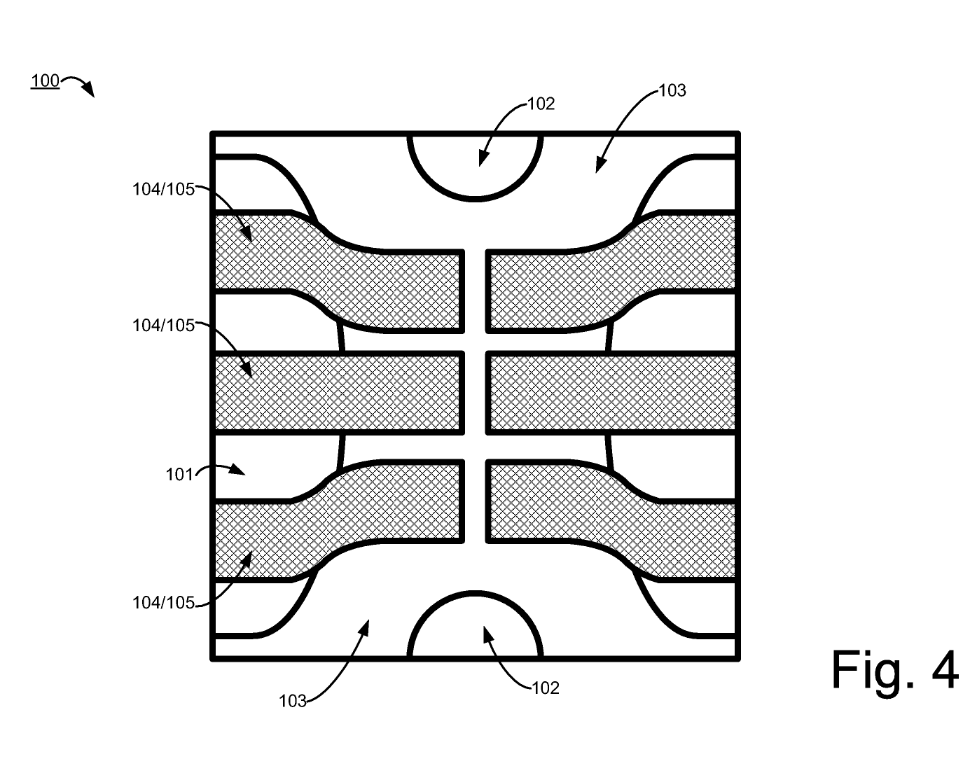

Top contacts may then be added. As shown in FIGS. 1 and 4 one or more layers 104, 105 may be added, as for example of a layer of calcium 104 (e.g., 20 nm Ca) and a layer of aluminum 105 (e.g., about 100 nm Al) deposited onto the top through a shadow mask (the shadow mask generating the pattern shown in FIG. 4, leaving exposed portions of the substrate 101, the ITO 102, the QD material 103 and then the top contacts 104/105).

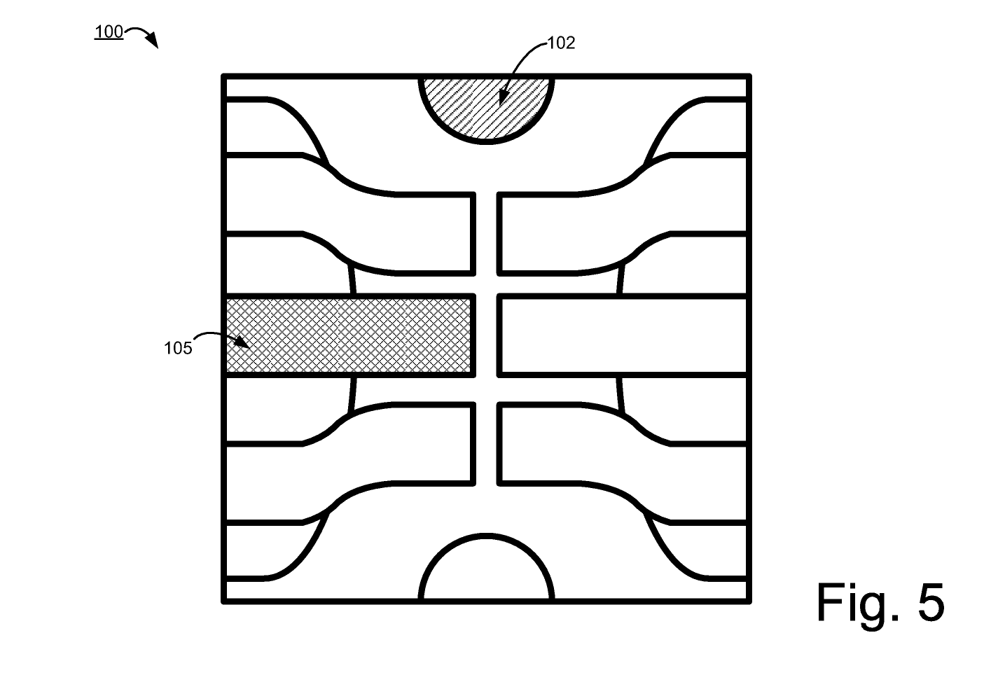

Here, then, each of six (6) devices are shown created on the chip 100. Each can be tested individually by probing (see FIG. 5, the probe from one of the top contacts 105, the other probe at an ITO 102 point to complete the circuit).

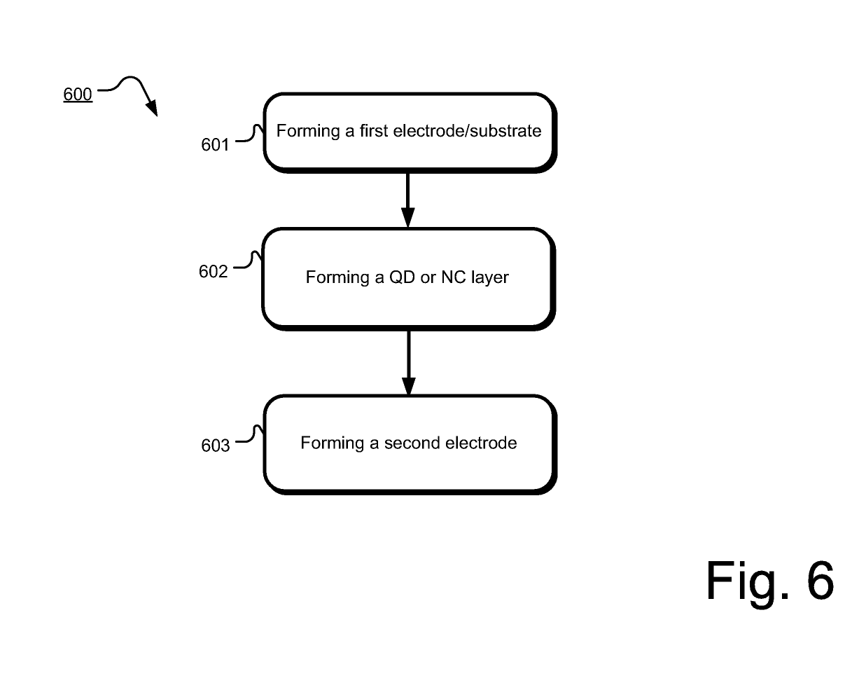

A method 600 is summarized in FIG. 6, including the first operation 601 of forming a first electrode/substrate, then forming a QD layer per operation 602. In summary form, the final operation 603 is forming a second electrode. Sub-part operations may be included, as for example within operation 603 may be included both forming a second electrode 104 of calcium with the following forming of an overlayer 105 of aluminum thereover.

In a more particular example, Schottky Solar Cells based on colloidal nanocrystal films may be formed as follows. The efficient generation of multiple electron-hole pairs from single photons in semiconductor nanocrystals (NCs) may provide for deploying chemically-synthesized nanomaterials in photovoltaic devices. To date, multiple exciton generation (MEG) has been studied in NCs of the lead salts, InAs, CdSe and Si using several time-resolved spectroscopies. However, demonstration of MEG photocurrent from a NC solar cell has been hindered by the poor external quantum efficiencies (EQEs) of existing NC devices. Here described is a simple, all-inorganic metal/NC/metal sandwich cell that produces a large short-circuit photocurrent (˜25 to 35 mA cm⁻²) by way of a Schottky junction at the negative electrode. The PbSe NC film, deposited via layer-by-layer (LbL) dip coating, yields an EQE of 65% across the visible and up to 25% in the infrared region of the solar spectrum, with a power conversion efficiency of 2.4%. Such an NC device produces larger short-circuit currents than any existing nanostructured solar cell, without the need for sintering, superlattice order or separate phases for electron and hole transport.

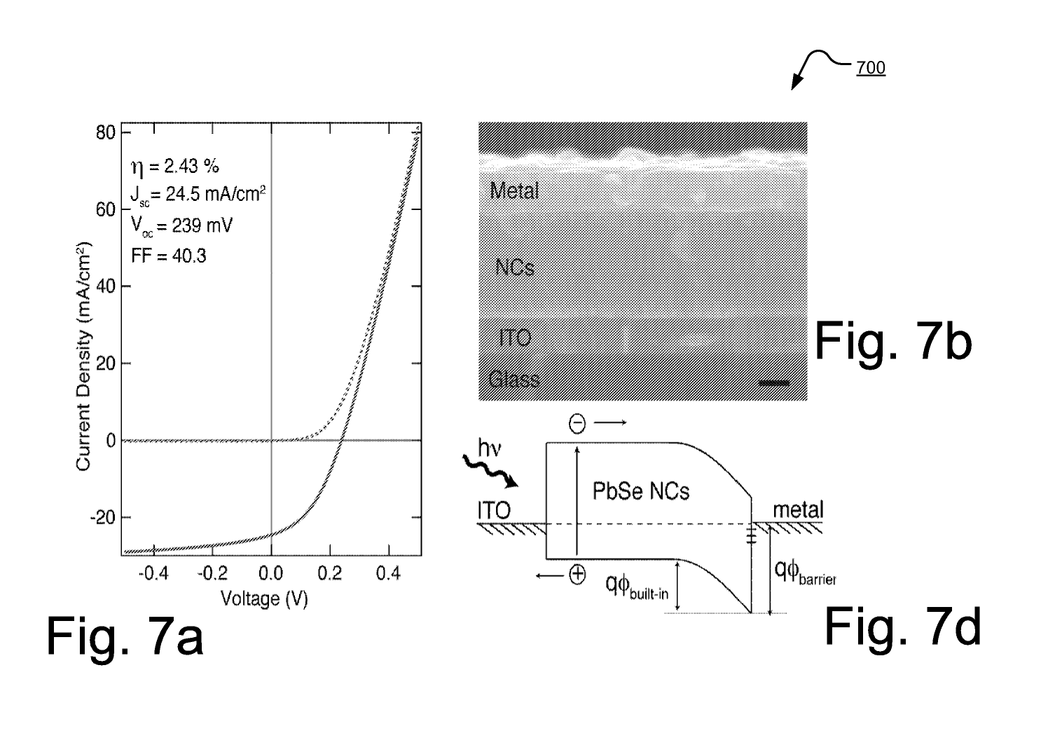

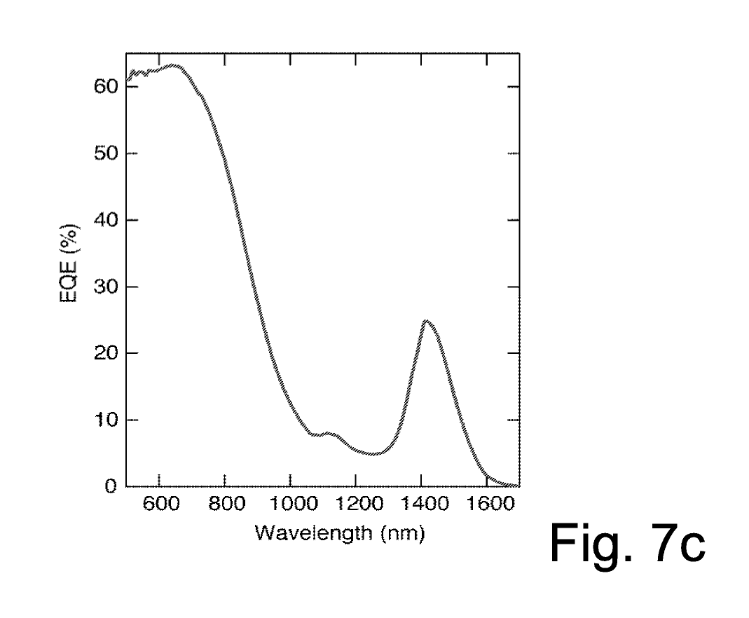

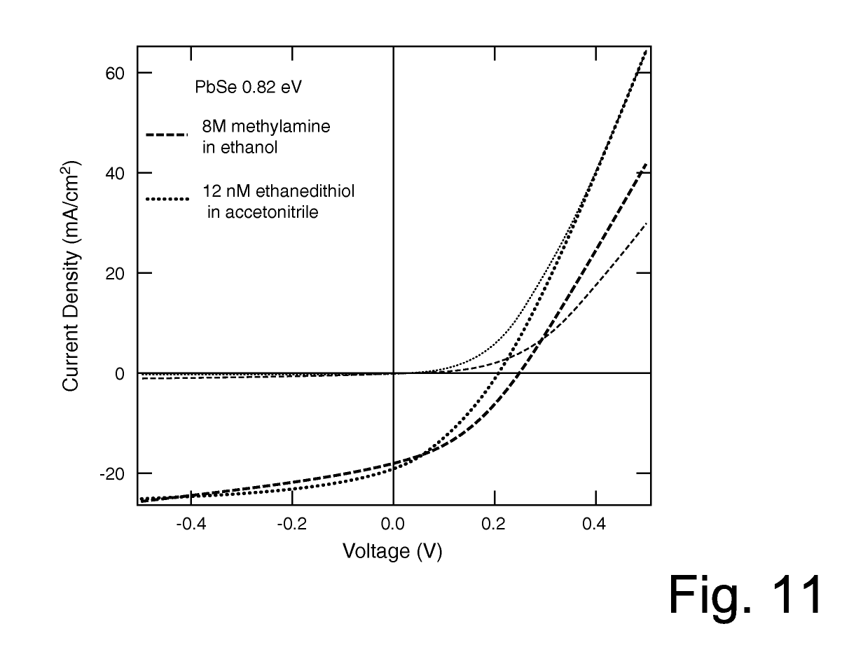

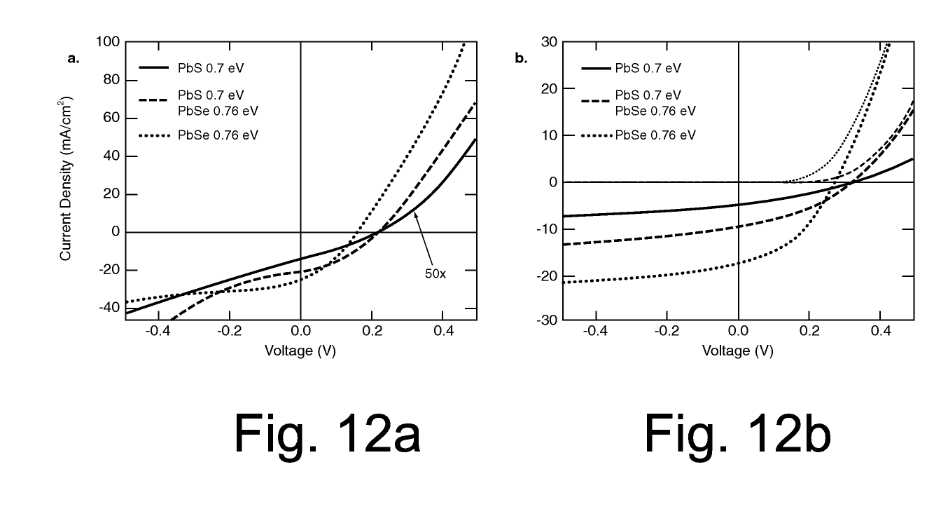

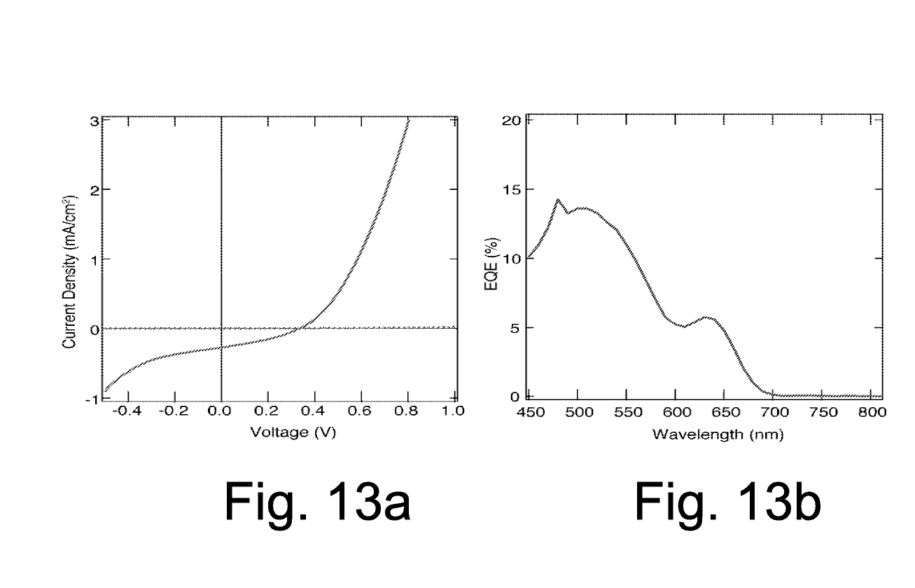

FIG. 7 shows the structure, current-voltage performance, EQE spectrum and band diagram of a further exemplary device 700 (see FIG. 7b). Device fabrication includes depositing a 60-300 nm-thick film of monodisperse, spheroidal PbSe NCs onto indium tin oxide (ITO) coated glass using a layer-by-layer dip coating method, followed by evaporation of a top metal contact. In this LbL method, a layer of NCs is deposited onto the ITO surface by dip coating from a hexane solution and then washed in 0.01 M1,2-ethanedithiol (EDT) in acetonitrile to remove the electrically-insulating oleate ligands that originally solubilize the NCs (see description below). Large-area, crack-free and mildly conductive (σ=5×10⁻⁵ S cm⁻¹) NC films result. The NCs, randomly packed within the films, are covered in adsorbed ethanedithiolate and show p-type DC conductivity under illumination. X-ray diffraction and optical absorption spectroscopy established that the NCs neither ripen nor sinter in response to EDT exposure. It has been found that using methylamine instead of EDT yields similar device performance (FIG. 11 set forth below). Also fabricated were working devices from PbS and CdSe NCs (FIGS. 12 and 13, below), which indicates that the approach adopted here is not restricted to EDT-treated PbSe and that it should be possible to improve cell efficiency by engineering the surface of the NCs to attain longer carrier diffusion lengths.

When tested in nitrogen ambient under 100 mW cm⁻² simulated sunlight, EDT-treated devices exhibit large short-circuit photocurrent densities (J_{SC}) and modest open-circuit voltages (V_{OC}) and fill factors (FF), with one of the most efficient devices yielding J_{SC}=24.5 mA cm⁻², V_{OC}=239 mV, FF=0.41 and an overall efficiency of 2.4% (FIG. 7a). This J_{SC} is reproducibly larger than that of any existing nanostructured solar cell, including the best organic and dye-sensitized devices, which is remarkable considering the unsintered, glassy microstructure of the NC films. The EQE of the device resembles the NC absorption spectrum and peaks at 55-65% in the visible region (FIG. 7c).

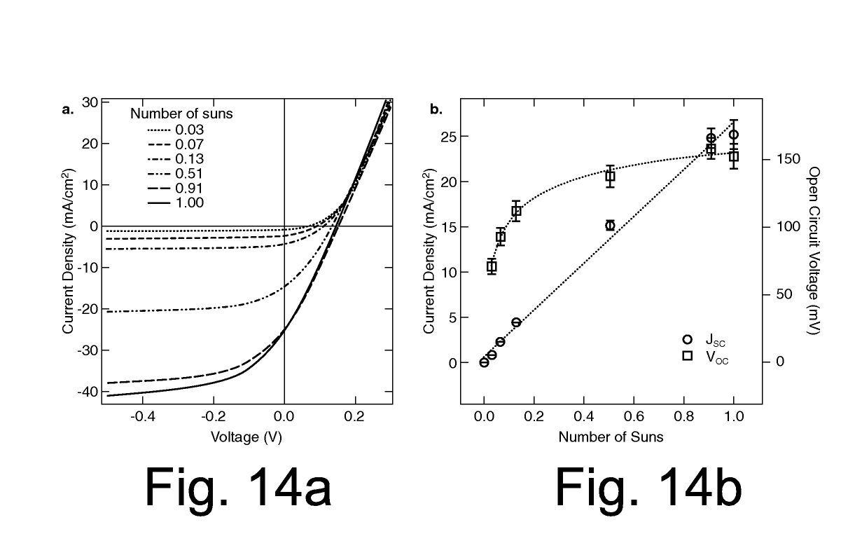

FIG. 7 sets forth the structure, performance and schematic diagram of the device. In FIG. 7a, the current-voltage characteristics of a representative device in the dark and under 100 mW cm⁻² simulated sunlight (E_{g}=0.9 eV). The J_{SC} and V_{OC} show the usual linear and logarithmic dependence on light intensity (FIG. 14, below). In FIG. 7b, scanning electron microscopy (SEM) cross-section of the ITO/NC film/metal device stack. The metal is 20 nm Ca/100 nm Al. The scale bar represents 100 nm. In FIG. 7c, External quantum efficiency (EQE) of a device with an efficiency of 2.2% (E_{g}=0.95 eV). In FIG. 7d, set forth is a proposed equilibrium band diagram. Light is incident through the ITO and band bending occurs at the interface between the NCs and evaporated negative electrode.

Multiple lines of evidence suggest that the photogenerated carriers in the device are separated by a Schottky barrier at the evaporated metal contact, as proposed in FIG. 7d. First, the open-circuit voltage (V_{OC}) of the cell increases with the NC bandgap, E_{g}, as

$${V}_{OC} \approx 0.49 \frac{{E}_{g}}{q} - 0.253 V$$

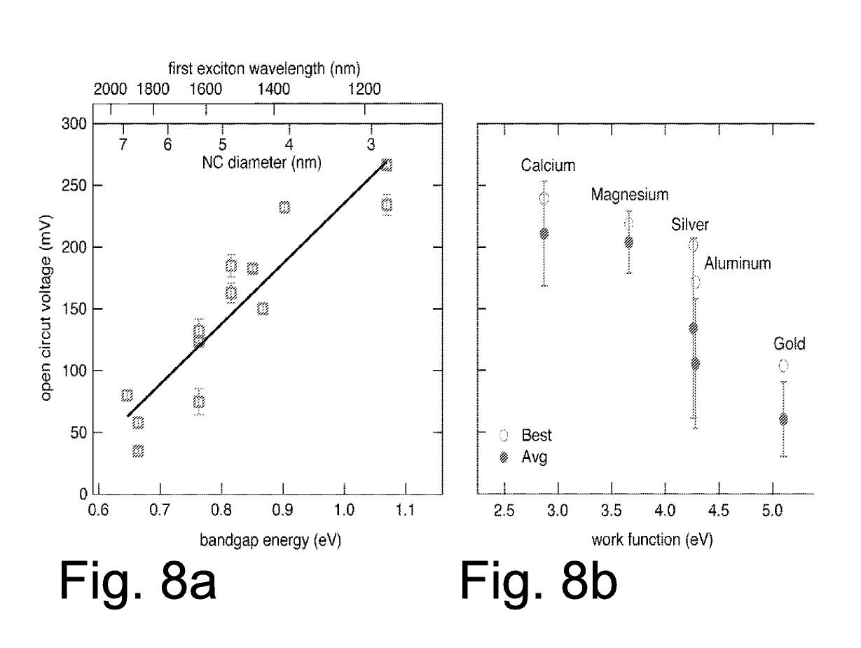

(FIG. 8a) where q is the charge of an electron. The V_{OC} of a Schottky cell should scale linearly with the barrier height, q _{B}, and, for an ideal contact between a metal and a p-type semiconductor, qφ_{B}=E_{g}−q(φₘ−χ), where φₘ is the work function of the metal and χ the electron affinity of the semiconductor. In view of the similar electron and hole effective masses in PbSe, equal displacement may be expected of the conduction and valence bands with increasing E_{g} and predict

$$Δ {V}_{OC} ∝ \frac{Δ {E}_{g}}{2 q}$$

for a metal/PbSe junction, close to the experimental result. This dependence should hold even if the Fermi level is pinned at the interface by surface states, provided that the surface states do not shift appreciably in energy with changes in E_{g}.

FIG. 8 sets forth trends in V_{OC} with NC size and metal work function. In FIG. 8a, dependence on NC size is shown. Each point is the average of six devices from a single substrate. The line is a least-squares fit to the data. In FIG. 8b, dependence on metal work function (E_{g}=0.82 eV) is provided. The best and average V_{oc} for each metal are shown, along with the standard deviation of six devices.

The second observation in support of the Schottky model is that the V_{OC} of the cell decreases with increasing work function of the top metal contact, as expected for a metal junction with a p-type semiconductor (FIG. 8b). However, changing the contact metal from gold to calcium (|Δφₘ|=2.3 eV) results in only a 0.15 V increase in V_{OC}, which suggests that the surface Fermi level is pinned and the barrier height is relatively independent of the metal. Schottky barrier formation is often due to defects formed at an interface by deposition of a metal, {PbSe specific reference . . . lead top contact} and this could easily be the case here. It may also be noted that devices with gold top contacts do not switch polarity (that is, gold does not become the positive electrode) despite the fact that the work function of gold is substantially larger than that of ITO. Such a polarity reversal is expected if the present devices were a metal-insulator-metal (MIM) type structure with a photovoltage driven by the difference in electrode work functions.

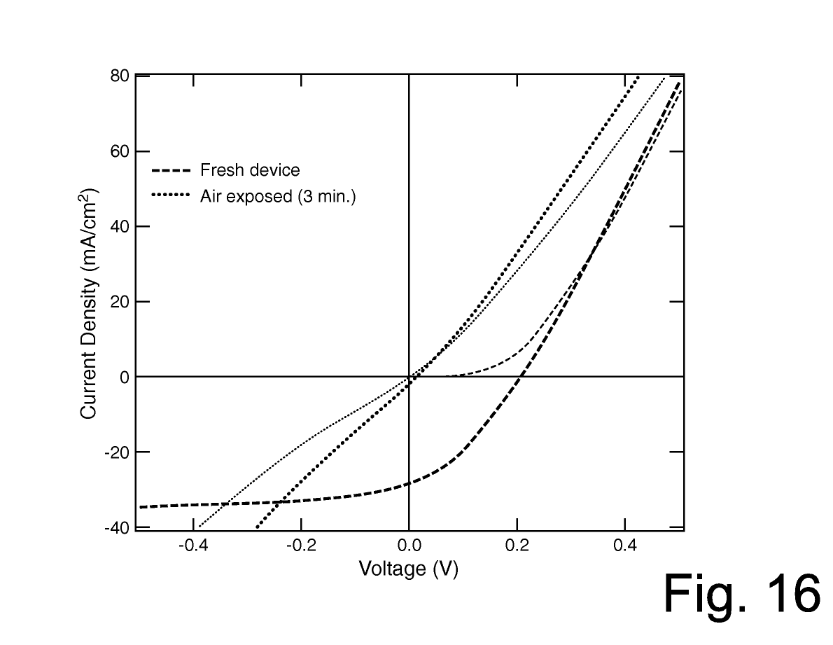

Direct evidence for the Schottky junction is obtained by capacitance-voltage (C-V) measurements on complete cells. The simple structure of devices permits a determination of the built-in potential, depletion width, and carrier concentration of the NC film by Mott-Schottky analysis. The analysis assumes no free carriers in the depletion region and a carrier concentration outside the depletion region equal to the total acceptor density. The depletion width, W, of an abrupt Schottky junction is equal to

$$W = \sqrt{\frac{2 {ɛ}_{0} ( {φ}_{bi} - V )}{qN}} , \qquad ( 1 )$$

where ∈₀ is the static dielectric constant of the NC film, φ_{bi} the built-in potential, V the applied bias, and N the free carrier density at the edge of the depletion layer, given by:

$$N = \frac{1}{{A}^{2}} \frac{2}{q {ɛ}_{0} \frac{d}{d V} ( \frac{1}{{C}^{2}} )} \qquad ( 2 )$$

where A is the device area and C the capacitance. A static dielectric constant of ∈₀=12 was used for the NC films discussed here, as calculated with Bruggeman effective media theory (FIG. 16, below).

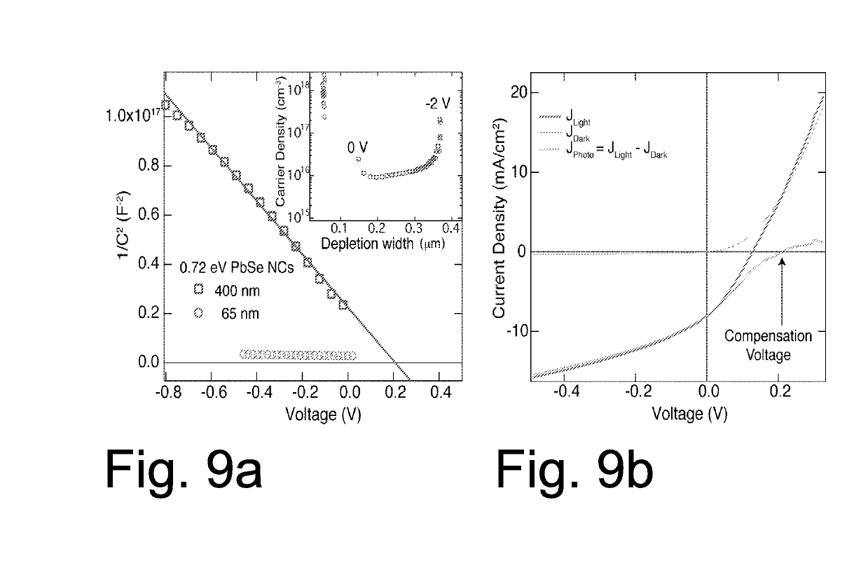

Mott-Schottky results for devices with a thin (65±5 nm) and thick (400±40 nm) NC layer are presented in FIG. 9a. The thick device behaves as an ideal p-type diode with a built-in potential of 0.2 V. The inset of FIG. 9a shows N as W increases with applied reverse bias. The depletion width of the thick film is 150 nm at equilibrium and increases to approximately 375 nm when the device nears full depletion at approximately 1.7 V in reverse bias. Its equilibrium carrier density is determined to be 10¹⁶ cm⁻³. Since W=150 nm for the thick device, the thin device (made from an identical NC film, only thinner) is fully depleted at equilibrium. Its capacitance (and thus W) therefore does not change appreciably with reverse bias, and its carrier density cannot be accurately determined from the slope of the Mott-Schottky plot.

FIG. 9 sets forth the analysis of the Schottky barrier. In FIG. 9a, provided are Mott-Schottky plots at 1 kHz for devices with a thin (65 nm, red) and thick (400 nm, blue) NC layer. The capacitance of the thin device is larger and changes little with reverse bias. A linear fit shows that the built-in potential of the thick device is 0.2 V. Note that smaller NCs yield larger built-in potentials (not shown), as expected from FIG. 8a. The inset shows the carrier concentration at the edge of the depletion layer for both devices. The thick device has an equilibrium depletion width of approximately 150 nm, while the thin device is fully depleted. In FIG. 9b, J-V characteristics are provided of the thick device. The photocurrent (J_{Light}-J_{Dark}) equals zero at a compensation voltage of 0.2 V.

The built-in potential found by C-V measurements is in agreement with the estimate from J-V plots. In a typical Schottky cell, the built-in potential is equivalent to the voltage at which the photocurrent (J_{Light}-J_{Dark}) becomes zero. FIG. 9b shows that this occurs at 0.2 V, in accord with the Mott-Schottky results of FIG. 9a.

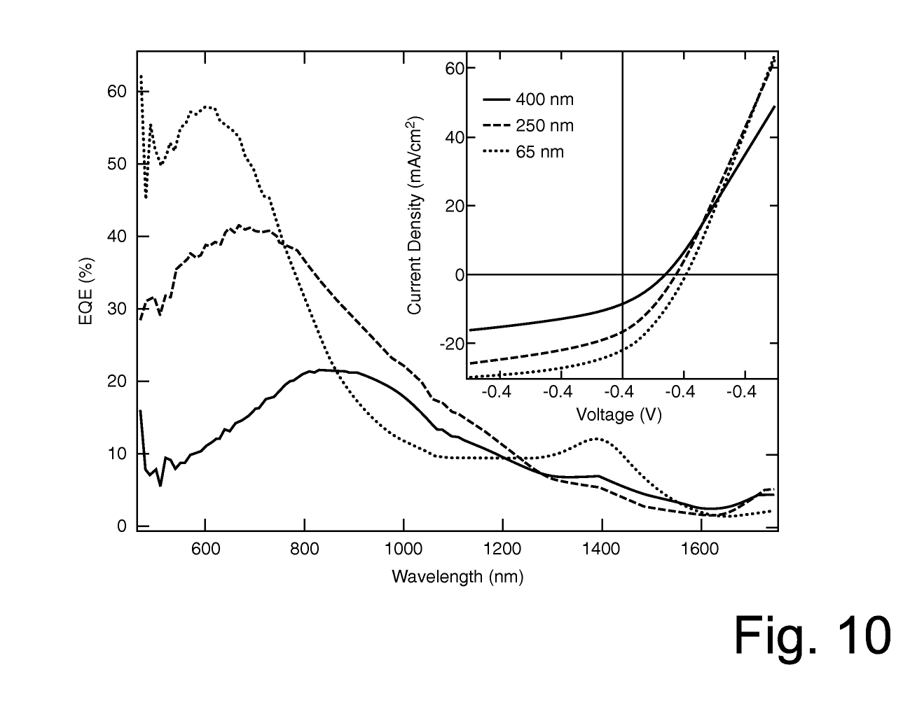

Deduction of the location of the Schottky junction may come from comparing the EQE spectra from cells of different thickness. It is shown in FIG. 10 that the EQE decreases markedly in the blue region of the spectrum as the thickness of the NC film is increased from 65 nm to 400 nm. This falloff in the blue suggests that the charge-separating junction occurs at the back contact, at the interface between the NC film and the evaporated metal electrode. Because thicker devices have a wider field-free region near the ITO, blue photons, which are absorbed nearer the front of the cell (1/α=75-100 nm at λ=450 nm), contribute progressively less to the photocurrent than do red photons, which penetrate closer to the depletion layer near the back contact. A back-contact Schottky geometry is consistent also with the polarity of the photocurrent and the C-V analysis presented above.

FIG. 10 sets forth the EQE dependence on NC film thickness. EQE spectra are provided for devices with NC film thicknesses of 65±5 nm, 250±40 nm and 400±40 nm. (E_{g}=0.72 eV). The inset shows the corresponding J-V traces at 100 mW cm⁻² illumination. Integration of each EQE curve with the solar spectrum yields the J_{SC} for each device.

Several additional observations can be made about the device based on the EQE and J-V data of FIG. 10. First, the diffusion length of excitons or carriers in the NC film must be fairly short, probably on the order of 100 nm; if it were much longer, the blue EQE decreases less sharply with increasing film thickness. Second, the V_{OC} is smaller for thicker devices, probably because more recombination occurs in the thicker films. The slope of the J-V plots in forward bias indicates a higher series resistance for thicker devices, caused by the longer transport distance and rougher surface of the thicker NC films. The device shunt resistance (dV/dJ_{V=0}) increases modestly with film thickness.

Demonstrating an EQE above 100% at 3E_{g} to 4E_{g} provides unequivocal proof of MEG photocurrent from a PbSe NC device. However, because cells show a maximum EQE of only 65%, a determination of the internal quantum efficiency or a comparison of the shape of the EQE and optical absorption spectra may be relied upon to identify any anomalously large photocurrents that might be attributable to MEG. A proper analysis is complicated by strong optical interference effects in these thin cells, and it is thus not certain whether MEG currents have been observed.

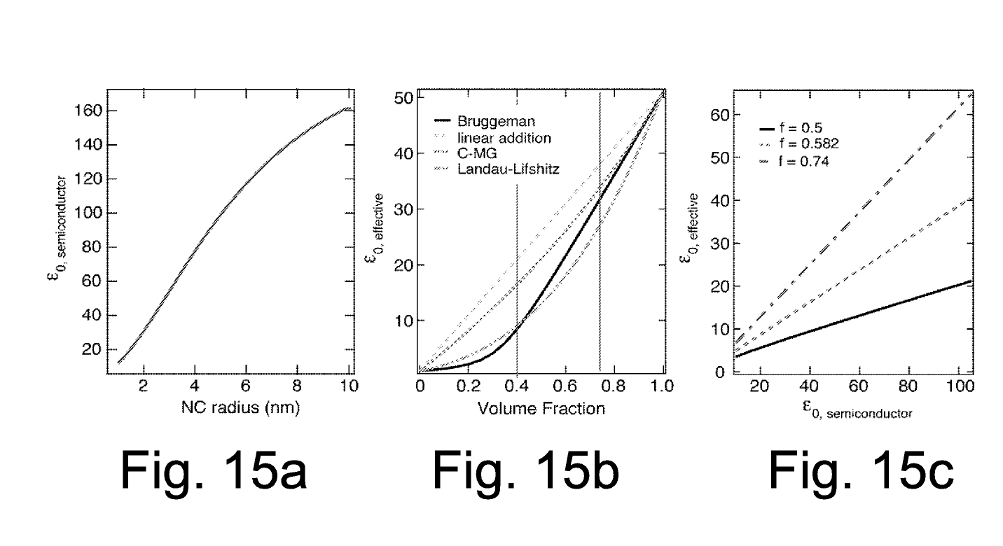

Some further observations may be made. First, the Schottky junction appears to be at the back rather than the front contact. This suggests building relatively thin cells which may make it difficult to achieve enough light absorption to yield higher EQEs and may thus complicate the search for MEG photocurrent. Second, some devices transform from a diode to a 50Ω resistor when exposed to air for several minutes (FIG. 15, below) suggesting further development of alternatives for the mechanism of device degradation and developing the means and mechanisms to prevent oxidation of the NC film. Finally, although as a Schottky cell the present device may produce only a relatively small V_{OC}, in theory little more than

$$\frac{{E}_{g}}{2 q} ,$$

which might suggest an NC p-n or p-i-n structure might be superior in this respect.

Thus introduced is a QD or NC solar cell which may be based on colloidal NC films. Moreover, as above, this may be an all-inorganic PbSe NC solar cell that produces a large short-circuit photocurrent by field-assisted separation of excitons and free carriers within a depletion region created near the interface of a NC film and a metal contact. This simple ITO/NC/metal device features a higher NC loading and fewer heterojunctions than either NC-sensitized Gratzel-type cells or NC/polymer blend designs, and outperforms existing lead salt NC cells at least fivefold. The present work demonstrates that large EQEs are obtainable from NC cells without the need for sintering, superlattice order or separate phases for electron and hole transport. An improved understanding of electronic coupling, surface passivation, doping and junction formation in NC films will lead to more efficient and stable NC solar cells.

Methods and materials in some implementations include use of Lead Oxide (PbO, 99.999%), selenium (99.99%), oleic acid (OA, tech. grade, 90%), 1-octadecene (ODE, 90%) and anhydrous solvents which were purchased from Aldrich and used as received. Trioctylphosphine (TOP, tech. grade, >90%), 1,2-ethanedithiol (EDT, >98%) and methylamine (33% in absolute ethanol) were acquired from Fluka.

NC synthesis may include standard airfree techniques used throughout. The PbSe NC synthesis is detailed above and results in monodisperse (within 10%), oleate-capped NCs. The following recipe was used to make NCs with E_{g}=0.8-0.9 eV: 1.1 g of PbO and 3.45 g of OA were dissolved in 13.52 g of ODE in a three-necked flask by heating the mixture to 160° C. 15 ml of 1 M TOP-Se was then rapidly injected into the hot solution. The solution was cooled with a water bath 30 seconds after injection. The NCs were purified by precipitation twice in hexane/acetone and at least once in hexane/ethanol and stored in a glove box as a powder.

Device fabrication may be as follows. In one example, all device fabrication occurred in a glove box. NC films were deposited onto patterned and cleaned ITO-coated glass substrates (12 Ω/sq., Colorado Concept Coatings) using a layer-by-layer dip coating process reported elsewhere. The substrates were dipped by hand into a 20-mL beaker containing a NC solution in hexane (6 mg/mL), followed by a second beaker containing 0.01 M EDT in acetonitrile. 25-40 dip coating cycles were used to make the films for devices. Top contacts were deposited through a shadow mask in a glove box thermal evaporator (10⁻⁷ Ton base pressure, Angstrom Engineering) at a rate of 0.2 Å s⁻¹ for the first 20 nm and 2.0 Å s⁻¹ for the remainder. Six devices were fabricated on each substrate, each with an active area of 0.11 cm².

Device characterization may include SEM imaging, including film thickness measurements, which in one example was performed on a JEOL JSM-700F. J-V and EQE data were acquired in a glove box with homemade setups. A calibrated filtered Si diode (Hamamatsu, S1787-04) served as the reference cell for J-V measurements. Spectral mismatch factors were calculated according to Shrotriya et al. to account for the spectral difference between the tungsten halogen lamp and the true AM1.5G solar spectrum. The mismatch was determined to be 0.8-1 depending on the band gap and thickness of the NC film. EQE measurements were taken with a fiber-coupled monochromator, a Stanford Research SR830 lock-in amplifier (locked to light chopped at 153 Hz), and a NIST-calibrated silicon diode (UDI, uv-100) for visible and a germanium diode (Judson, J1651-8A4-RO3M-SC) for NIR wavelengths. Capacitance-voltage measurements were performed on devices in an airfree cell with an Agilent 4294a precision impedance analyzer. Mott-Schottky plots were linear and well-behaved for modulation frequencies spanning two orders of magnitude (1 kHz data were shown). The sampling amplitude for C-V measurements was 50 mV_{RMS}.

The above describes the use of 1,2-ethanedithiol (EDT) to replace the oleate ligands on PbSe nanocrystal (NC) films in order to fabricate NC solar cells. For the sake of generality, cells have also been made using methylamine (MA) to remove the oleate. In addition, working devices have been made from PbS and CdSe NCs using EDT. FIG. 11 shows that MA-treated devices can achieve equally large short-circuit currents as EDT-treated devices. The layer-by-layer deposition of the film with MA required approximately twice as many dip-coating cycles to achieve a similar optical density. FIG. 12 compares the J-V plots of devices made from PbSe NCs, PbS NCs, and PbSe/PbS NC blends. PbSe NC devices achieve a higher J_{SC} but lower V_{OC} than do PbS NC devices. The blend devices retain the larger V_{OC} of the PbS-only devices, while the J_{SC} of the blend lies between the values of the single component devices.

More specifically, FIG. 11 provides comparative J-V curves of devices fabricated using EDT and methylamine (MA). EDT and MA concentrations are indicated. The V_{OC} is slightly higher in the MA-treated film, but the J_{SC} values are nearly equal. (E_{g}=0.82 eV).

More specifically, FIG. 12 provides comparative J-V curves for Bulk heterojunction PbSe/PbS NC devices. In FIG. 12a, J-V curves are provided of devices made from PbSe NCs, PbS NCs, and PbSe/PbS NC blends (1:1 by weight). The NCs have a band gap of approximately 0.73 eV. The current density of the PbS-only device has been multiplied by a factor of 50. The PbS-only device shows a higher V_{OC}, while the PbSe-only device shows a higher J_{SC}. The blend device achieves most of the J_{SC} of the PbSe-only device and retains the V_{OC} of the PbS-only device. In FIG. 12b, provided are the J-V plots of devices made from PbSe and PbS NCs with a band gap of approximately 1.1 eV. The results are essentially the same, except that the current of the PbS-only device is higher than in FIG. 12a.

FIG. 13 shows J-V and external quantum efficiency data of an ITO/NC/metal device employing a CdSe NC film produced by layer-by-layer dip coating using EDT. No effort has been made to elucidate the effect of the EDT treatment on the CdSe NCs or to optimize these devices. The current generated in the CdSe devices is much lower than what was observed in lead salt devices, probably because of the poorer inter-NC electronic coupling and higher charging energy associated with CdSe. In addition, it was found that the CdSe devices have better air stability than the PbSe devices.

More particularly, FIG. 13 shows results for a CdSe NC Schottky solar cell. In FIG. 13a, J-V characteristics are provided of a device employing CdSe NCs as the absorbing layer and Ca/Al as the top contact. The NCs have a band gap of 2.0 eV (618 nm) in solution. Virtually no current flows in this device in the dark (dotted line). In FIG. 13b, the EQE of the same device is provided. Note that integration of the EQE with the solar spectrum yields a much larger J_{SC} than is shown in FIG. 13a, which suggests a nonlinear dependence of J_{SC} with light intensity in this device.

The performance of a PbSe NC device as a function of light intensity is shown in Supplementary FIG. 14. The J_{SC} and V_{OC} data show linear and logarithmic dependences on light intensity, as expected for solar cells.

More particularly, FIG. 14 shows dependence of device performance on light intensity. In FIG. 14a, provided are J-V curves and in FIG. 14b, J_{SC} and V_{OC} as a function of light intensity is shown. Light intensity was modulated using neutral density filters. The number of suns was calculated by multiplying the measured wavelength-dependent absorbance of the filters by intensity of the light source. The average value and standard deviation of the six devices on the substrate are shown in FIG. 14b.

In the Mott-Schottky analysis presented here, an assumption was made regarding the value of the static dielectric constant, ∈₀, of the NC film. Calculations were begun with a value of 210 for the bulk static dielectric constant of PbSe. Due to surface polarization effects, the dielectric constant is reduced in NCs relative to its bulk value. Using the Penn approximation, an estimate of the value of the dielectric constant for the quantum-confined NCs used in FIG. 9 of the text (0.72 eV, 2.5 nm radius) was determined to be approximately 50. Ben-Porat et al. measured the dielectric constant of PbSe NCs to be approximately 100 for 5.5 nm diameter PbSe NCs, consistent with the Penn approximation used here. In addition to accounting for the size effect, an effective medium approximation (EMA) is made to account for the void space and residual organic capping molecules associated with the packing of substantially spherical PbSe NCs into films (see e.g., FIG. 1, and noting again that no particular shape of NCs is intended as limiting herein, spherical or otherwise). The volume fraction of randomly-packed hard spheres was calculated by Furukawa et al. to be 0.58, while for close-packed hard spheres it is 0.74. NCs pack randomly in the EDT-treated films, but the true volume fraction of PbSe is probably somewhat less than 0.58 because of the presence of adsorbed EDT. Settled on was 0.5 as a likely value for the volume fraction in the films. FIG. 15 shows the calculated results of the effective dielectric constant of the NC films, ∈_{0,effective}, accounting for both NC size effects and the EMA. The C-V analysis here employs the Bruggeman approximation, whereby a 2.5 nm radius PbSe NC (∈₀=50) and a filling fraction of 0.5 corresponds to ∈_{0,effective}=12. These calculations have been validated against C-V results from devices composed of smaller NCs.

More particularly, FIG. 15 provides calculations of the static dielectric constant of the PbSe NC films. In FIG. 15a, NC permittivity is provided as a function of NC radius, as determined using the Penn approximation. In FIG. 15b, effective static dielectric constant of NC films (2.5 nm radius, E_{g}=0.72 eV) is provided using the Bruggeman, cavity-Maxwell-Garnett, Landau-Lifshitz, or linear addition effective media approximations as a function of the volume fraction of the NCs. In FIG. 15c, effective static dielectric constant of the NC films is shown as a function of NC size using FIG. 15a and the Bruggeman approximation for volume fractions of 0.5, 0.582 and 0.74.

The air stability of the EDT-treated PbSe NC devices was poor. All fabrication and characterization was performed inside glove boxes and extreme care was taken to prevent oxygen exposure. FIG. 16 shows J-V curves for a fresh PbSe NC device measured in the glove box and for the same device measured after exposure to air for 3 minutes. More particularly, FIG. 16 provides a view of stability of the PbSe NC devices. Light and dark J-V curves for a 1.8% efficient device freshly made (red) and after a 3-minute air exposure (blue).

It is noted that the examples discussed above are provided for purposes of illustration and are not intended to be limiting. Still other embodiments and modifications are also contemplated.

While a number of exemplary aspects and embodiments have been discussed above, those of skill in the art will recognize certain modifications, permutations, additions and sub combinations thereof. It is therefore intended that the following appended claims and claims hereafter introduced are interpreted to include all such modifications, permutations, additions and sub-combinations as are within their true spirit and scope.

1. A solar cell comprising:
a first electrode;
a nanocrystal film of a single material disposed in contact with the first electrode; and
a second electrode disposed in contact with the nanocrystal film, not in contact with the first electrode.

2. A solar cell according to claim 1 wherein the nanocrystal film is one or more of: a quantum dot material, and a colloidal nanocrystal material.

3. A solar cell according to claim 1 wherein the nanocrystal film is one or more of a single quantum dot material of: lead sulfide, lead selenide, cadmium selenide, lead telluride, silicon, germanium, indium phosphide, gallium arsenide, indium arsenide, and all Groups IV, Group III-V, and Group II-VI semiconductor binary and ternary compounds and alloys, or core-shell-like configurations.

4. A solar cell according to claim 1 wherein the first electrode is a thin metal film allowing for the transmission of sunlight.

5. A solar cell according to claim 1 wherein the first electrode is indium tin oxide.

6. A solar cell according to claim 1 wherein the first electrode is disposed on a glass substrate.

7. A solar cell according to claim 1 wherein the second electrode is one of aluminum, gold, silver or magnesium.

8. A solar cell according to claim 1 wherein the second electrode is calcium.

9. A solar cell according to claim 1 wherein the second electrode has an encapsulant.

10. A solar cell according to claim 1 wherein aluminum is an encapsulant over the second electrode.

11. A solar cell according to claim 1 wherein the second electrode forms a Schottky junction with the nanocrystal film.

12. A solar cell according to claim 1 wherein the first electrode is a transparent conductor forming an ohmic contact with the QD film and the second electrode is a metal with a work function different from the first electrode and also forms an ohmic contact with the QD film.

13. A solar cell according to claim 1 wherein the first and second electrodes are heavily doped n-type and p-type electrodes respectively, both electrodes form ohmic contacts with the QD film, and the first electrode is transparent to sunlight.

14. A solar cell according to claim 1 wherein the first and second electrodes are heavily doped n-type and p-type electrodes respectively, both electrodes form ohmic contacts with the QD film, and the second electrode is transparent to sunlight.

15. A solar cell according to claim 1 wherein the nanocrystal film is a layer-by-layer deposited film of nanocrystal material alternately in a plurality of cycles.

16. A solar cell according to claim 1 wherein the nanocrystal film is a layer-by-layer deposited film of nanocrystal material alternately added and coated with ligand exchange material in a plurality of cycles.

17. A method for making a solar cell comprising:
obtaining a first electrode;
forming a nanocrystal film of a single material in contact with the first electrode; and
forming a second electrode in contact with the nanocrystal film, not in contact with the first electrode.

18. A method according to claim 17 wherein the nanocrystal film is one or more of a single material of: lead sulfide, lead selenide, cadmium selenide, lead telluride, silicon, germanium, indium phosphide, gallium arsenide, indium arsenide, and all Groups IV, Group III-V, and Group II-VI semiconductor binary and ternary compounds and alloys.

19. A method according to claim 17 wherein the nanocrystal film is a layer-by-layer deposited film of nanocrystal materials alternately added in a plurality of cycles.

20. A method according to claim 17 wherein the forming of the nanocrystal film includes a layer-by-layer deposition including a plurality of cycles of alternately adding nanocrystal material and coating the nanocrystal material with ligand exchange material.

21. A method according to claim 17 wherein the first and second electrodes are heavily doped n-type and p-type electrodes respectively, both electrodes form ohmic contacts with the QD film, and one or both of the first and second electrodes is transparent to sunlight.
